(19) United States
(12) Patent Application Publication
(10) Pub. No.: US 2010/0124141 A1
(43) Pub. Date: May 20, 2010

(54) SEMICONDUCTOR MEMORY DEVICE OF DUAL-PORT TYPE

(75) Inventor: Tetsuya ARAI, Tokyo (JP)

Correspondence Address: YOUNG & THOMPSON, 209 Madison Street, Suite 500, Alexandria, VA, 22314, US

(73) Assignee: ELPIDA MEMORY, INC., Tokyo (JP)

(21) Appl. No.: 12/620,276

(22) Filed: Nov. 17, 2009

(30) Foreign Application Priority Data
Nov. 17, 2008 (JP) 2008-293272

(51) Int. Cl. G11C 8/16

(52) U.S. Cl. 365/230.05; 365/189.011

(57) ABSTRACT

To provide a plurality of DRAM cells, a plurality of sense amplifiers connected to corresponding bit line pairs, a first column switch and a second column switch assigned to each of the sense amplifiers, data lines connected via the column switches to the sense amplifiers, a first port PORT1 and a second port PORT2 that can input/output write data and read data, and an input/output circuit that connects the PORT1 and the PORT2 to the data lines. Thus, a pseudo dual-port memory can be configured by using an ordinary DRAM array.

### BACKGROUND OF THE INVENTION

1. Field of the Invention

The present invention relates to a semiconductor memory device, and more particularly relates to a dual-port type semiconductor memory device (a dual-port memory).

2. Description of Related Art

The dual-port memory has two input/output ports and can access the same memory space from these ports at the same time. It is used as an intermediary for data passing when devices that need to directly access memories or randomly access buffer regions, such as CPUs and peripheral controllers communicate with each other. Conventionally, the dual-port memories utilize SRAMs in most cases. Japanese Patent Application Laid-open No. 2004-86970 proposes a method of realizing the dual-port memory by using a DRAM.

FIG. 15 is a circuit diagram showing a configuration of principal parts of the dual-port memory proposed in JP-A No. 2004-86970.

A DRAM memory cell 301 shown in FIG. 15 is shared by a transfer gate 302 selected by a word line WD0a and a transfer gate 303 selected by a word line WD0b. The transfer gate 302 is a switch that connects the memory cell 301 to a sense amplifier 304 and the transfer gate 303 is a switch that connects the memory cell 301 to a sense amplifier 305. Data in the sense amplifier 304 is provided by a column select signal YS0a to an input/output port (PORT1) 306 and data in the sense amplifier 305 is provided by a column select signal YS0b to an input/output port 307 (PORT2). That is, the sense amplifiers are assigned to the input/output ports 306 and 307, respectively.

Because such a configuration enables a free row access and a column access other than a case that different data are written for the same address, the respective input/output ports can access independently the same memory array. Because the memory cell is a DRAM cell, an initial read period from when the word line rises to when the sense amplifier is activated is susceptible to noise. When large adjacent noise occurs, data may be inverted. However, according to the dual-port memory shown in FIG. 15, when the write operation is performed upon a sense amplifier 308 that has been activated during a period from when the word line WD0a is selected to when the sense amplifier 304 is activated, large adjacent noise is applied to the sense amplifier 304. Thus, the sense amplifier 304 will amplify wrong data. To solve such a problem, the write operation upon the sense amplifier 308 needs to wait until the amplification of the sense amplifier 304 is completed.

In this way, the dual-port memory described in JP-A No. 2004-86970 requires measures against noise that is characteristic of the DRAM memory cell. A smooth clock synchronization operation may not be performed or the clock cycle needs to be extended significantly. The same numbers of the word lines, the bit lines, and the sense amplifiers as the number of the ports need to be prepared, so that the memory array may become about twice larger.

### SUMMARY

The present invention seeks to solve one or more of the above problems, or to improve upon those problems at least in part.

In one embodiment, there is provided a semiconductor memory device comprising: a memory cell array including a plurality of word lines, a plurality of bit lines, a plurality of DRAM cells arranged at intersections of the word lines with the bit lines, a plurality of sense amplifiers connected to corresponding bit lines, and a first column switch and a second column switch assigned to each of the sense amplifiers; a first data line and a second data line connected via the first column switch and the second column switch to the sense amplifiers, respectively; a first port and a second port each of which can input a write data to be inputted to the memory cell array and can output read data outputted from the memory cell array; and an input/output circuit that connects the first and second ports to the first and second data lines.

Because the present invention employs a pseudo dual-port configuration with a slightly broader definition of a dual-port memory, it is possible to provide a dual-port memory capable of achieving appropriate dual-port access while maintaining a clock cycle.

### BRIEF DESCRIPTION OF THE DRAWINGS

The above features and advantages of the present invention will be more apparent from the following description of certain preferred embodiments taken in conjunction with the accompanying drawings, in which:

FIG. 1 is a circuit diagram showing a configuration of principal parts of a semiconductor memory device 400 according to a first embodiment of the present invention;

FIG. 2 is a circuit diagram showing a configuration of memory cell array 201;

FIG. 3 is a circuit diagram of a detection circuit 130c for generating address transition detection signals AT and ATD;

FIG. 4 is a timing diagram showing an operation timing when the write request and the read request are issued at the same time and the read address is the same as the write address according to the first embodiment;

FIG. 5 is a circuit diagram showing a configuration of principal parts of a semiconductor memory device 500 according to the second embodiment of the present invention;

FIG. 6 is a circuit diagram of a detection circuit 130e;

FIG. 7 is a circuit diagram of showing a modified configuration of principal parts of the semiconductor memory device 500;

FIG. 8 is a circuit diagram of a detection circuit 130f;

FIG. 9 is a circuit diagram of a detection circuit 130d;

FIG. 10 is a timing diagram showing an operation timing when the simultaneous issue of the write request and the read request is performed consecutively and the read address is the same as the write address according to the third embodiment;

FIG. 11 is a circuit diagram showing a configuration of principal parts of a semiconductor memory device 600 according to the fourth embodiment of the present invention;

FIG. 12 is a circuit diagram of a detection circuit 130g;

FIG. 13 is a circuit diagram of showing a modified configuration of principal parts of the semiconductor memory device 600;

FIG. 14A shows one mat array configuration;

FIG. 14B shows plural mat arrays configuration having a hierarchical data line configuration;

FIG. 14C shows a configuration divided into plural banks; and

FIG. 15 is a circuit diagram showing a configuration of principal parts of the dual-port memory proposed in JP-A No. 2004-86970.

### DETAILED DESCRIPTION OF THE EMBODIMENTS

Preferred embodiments of the present invention will be explained below in detail with reference to the accompanying drawings.

Data passing through the dual-port memory is usually performed by one port connected to a controller device and the other port connected to an output device. In this case, the controller device performs mainly the write operation and the output device performs mainly the read operation. According such usage, it is thus important to be able to perform the write operation and the read operation at the same time.

The first embodiment provides a memory that can perform the read operation and the write operation at the same time for the same row address. The address that the read operation and the write operation can be performed at the same time is narrowed down to the same row address, so that a multi-access period can be determined as only after amplification of a sense amplifier and influences of noise during DRAM's initial read operation does not need to be considered. Because full-page data can be processed, a hit probability can be increased by devising access methods. Specifically, the dual-port memory is configured as follows. That is, arbitration circuits sharing a write path by a dual-port and sharing a read path by a dual-port are added to the memory core that can perform the read operation and the write operation at the same time. In an arbitration method, when one port is assigned to the write path, the other port is assigned to the read path. The simultaneous read and write operations in the dual-port can be realized by operating the write path and the read path at the same time. While sharing one data path by the dual-port has been conventionally suggested, the present invention is different from conventional methods in that the simultaneous operations can be performed in the dual-port. It is important that a sense amplifier corresponding to memory cells in a column operation is shared by the dual-port. That is, only the column operation is provided, but the dual-port memory is used.

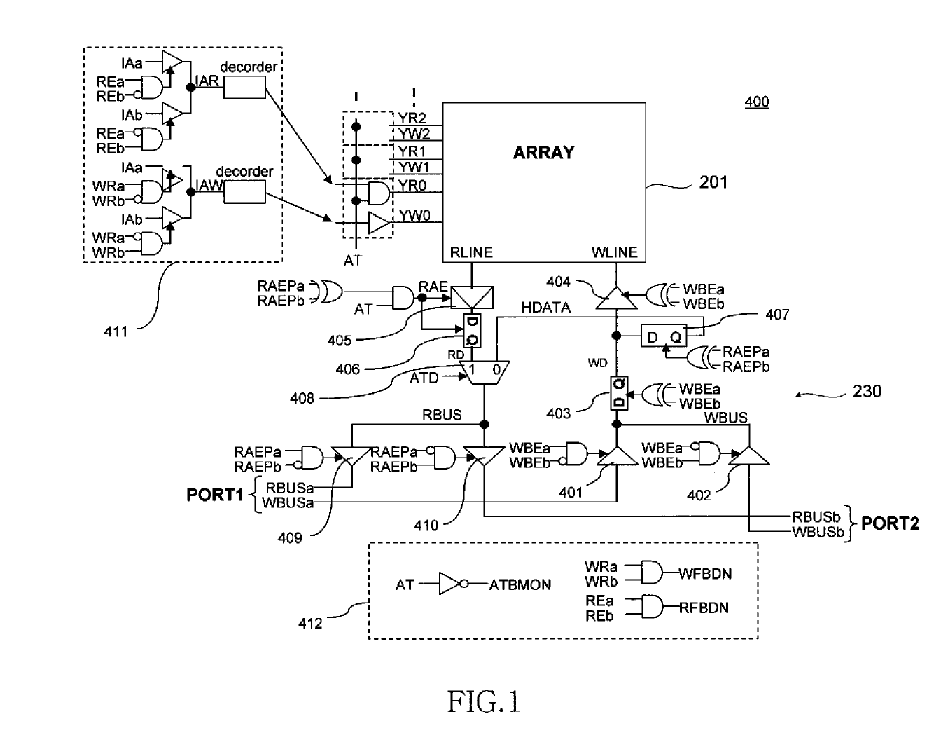

FIG. 1 is a circuit diagram showing a configuration of principal part of a semiconductor memory device 400 according to the first embodiment of the present invention. The semiconductor memory device 400 according to the first embodiment is a DRAM.

As shown in FIG. 1, the semiconductor memory device 400 according to the first embodiment includes a memory cell array 201, a data line RLINE for read and a data line WLINE for write connected to the memory cell array 201, two ports PORT1 and PORT2, and an input/output circuit 230 that connects the PORT1 and the PORT2 to the data line RLINE for read and the data line WLINE for write.

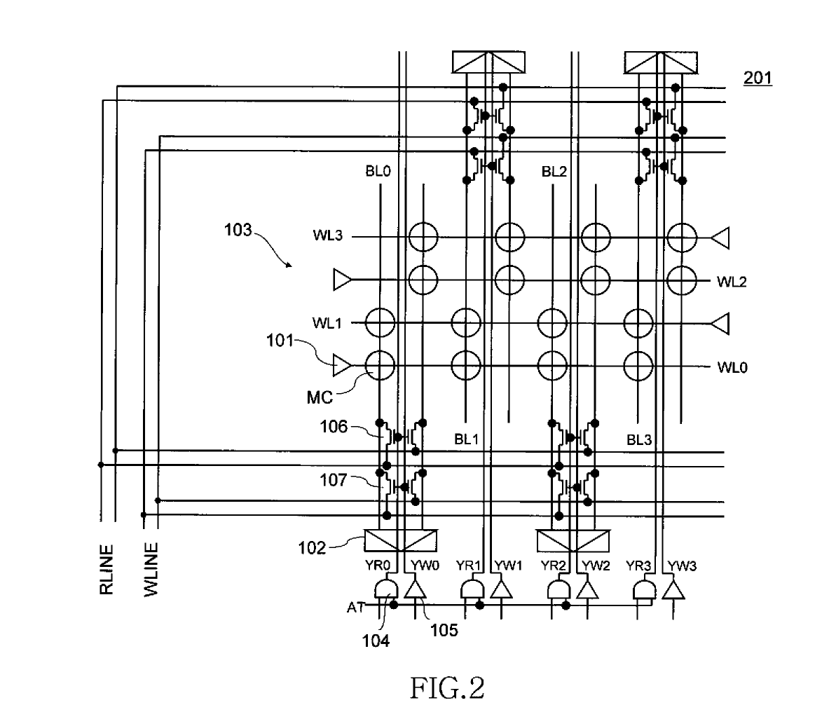

FIG. 2 is a circuit diagram showing a configuration of the memory cell array 201.

As shown in FIG. 2, the memory array 201 includes a memory cell array 103 including word lines WL0, WL1, . . . , bit line pairs BL0, BL1, . . . , and memory cells MC arranged at intersections of the word lines with the bit lines. The word lines WL0, WL1, . . . are driven by corresponding word drivers 101. A sense amplifier 102 is connected to each of the bit line pairs BL0, BL1, . . . . Each sense amplifier 102 is connected via a corresponding column switch 106 to the data line RLINE for read and via a corresponding column switch 107 to the data line WLINE for write. Column select signals YR0, YR1, . . . for read serving as outputs of column select drivers 104 for read are supplied to the respective column switches 106 and any one of the switches is turned on during the read operation. Column select signals YW0, YW1, . . . for write serving as outputs of column select drivers 105 for write are supplied to the respective column switches 107 and any one of the switches is turned on during the write operation.

The data line RLINE for read is a wiring for transmitting complementary read data and connected to the input/output circuit 230 shown in FIG. 1. The data line WLINE for write is a wiring for transmitting complementary write data and connected to the input/output circuit 230 shown in FIG. 1. The circuit shown in FIG. 2 corresponds to one bit of I/O in the memory array 201.

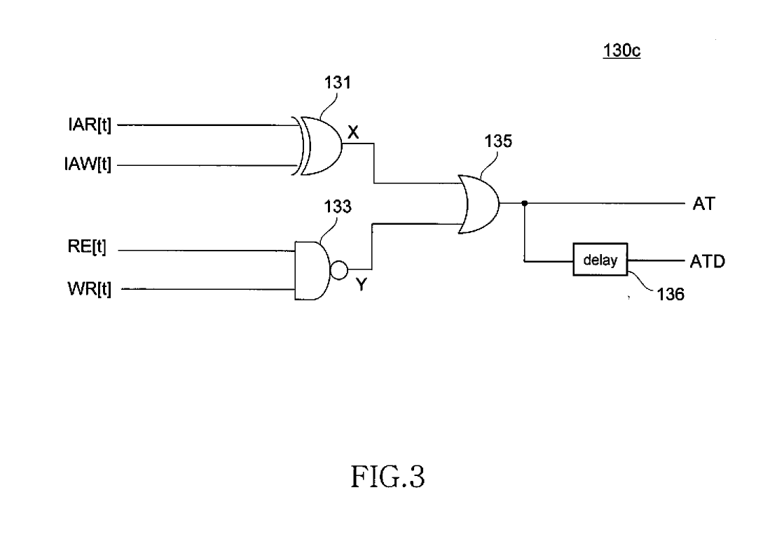

As shown in FIG. 1, the PORT1 and the PORT2 share a write bus WBUS for write operation and a read bus RBUS for read operation. Address transition detection signals AT and ATD can use a detection circuit 130c shown in FIG. 3.

FIG. 3 is a circuit diagram of the detection circuit 130c that generates the address transition detection signals AT and ATD.

As shown in FIG. 3, a current read address IAR[t], a current write address IAW[t], a current read-state flag RE[t], and a current write-state flag WR[t] are supplied to the detection circuit 130c. The “state flag” means a signal that becomes “H” when a corresponding cycle is in a corresponding state and becomes “L” in otherwise cases.

The current read address IAR[t] and the current write address IAR[t] are supplied to an EXOR gate 131. When the current read address IAR[t] matches with the current write address IAW[t], the EXOR gate 131 sets an output X to L. In other cases, the output X is maintained at a high level.

The current read-state flag RE[t] and the current write-state flag WR[t] are supplied to a NAND gate 133. Accordingly, when the write operation and the read operation are requested at the same time, the NAND gate 133 sets an output Y to L. In other cases, the output Y is maintained at a high level.

The outputs X and Y are supplied to an OR gate 135. Only when the write request and the read request are issued at the same time and the read address is the same as the write address, the address transition detection signal AT becomes “L”.

The address transition detection signal AT is supplied to a delay circuit 136. An output of the delay circuit 136 is the delay address transition detection signal ATD. The delay address transition detection signal ATD is obtained by delaying the address transition detection signal AT to adjust timing.

Accordingly, when the write request and the read request are received at the same address, write data is written in the array and can be returned as read data as described later.

Each piece of port data is sorted as follows. With reference to FIG. 1, signals with a suffix a being attached thereto are signals for PORT1 and signals with a suffix b being attached thereto are signals for PORT2.

The write operation is described first. When the PORT1 performs the write operation but the PORT2 does not perform the write operation, a gate of a tri-state buffer 401 is opened and write data of the PORT1 is supplied to the write bus WBUS. On the other hand, when the PORT1 does not perform the write operation but the PORT2 performs the write operation, a gate of a tri-state buffer 402 is opened and write data of the PORT2 is supplied to the write bus WBUS. In this way, the write data from each port is placed on the common write bus WBUS in a separated manner. Because a hold circuit 403 needs to hold the write data from either port, it is operated depending on an exclusive-OR output of write buffer activation signals WBEa and WBEb.

The read operation is described next. As a read amplifier 405 and a hold circuit 406 need to be activated when the PORT1 performs the read operation but the PORT2 does not perform the read operation or when the PORT1 does not perform the read operation but the PORT2 performs the read operation, they are activated depending on an exclusive-OR output of activation signals RAEPa and RAEPb. A hold circuit 407 is also activated depending on an exclusive-OR output of the activation signals RAEPa and RAEPb. A multiplexer 408 then selects an input 1 or an input 0 and the signal of the selected input is supplied to the read bus RBUS. When the PORT1 performs the read operation but the PORT2 does not perform the read operation, the data is outputted via a tri-state buffer 409 to the PORT1. When the PORT1 does not perform the read operation but the PORT2 performs the read operation, the data is outputted via a tri-state buffer 410 to the PORT2.

The addresses of the PORT1 and the PORT2 are sorted into an address for a read operation IAR and an address for a write operation IAW by using a selection circuit 411 for use. The addresses of the PORT1 and the PORT2 are also used for generating the address transition detection signal AT. According to the present embodiment, cases that the write operation is performed at the same time in the PORT1 and the PORT2 and the read operation is performed at the same time in the PORT1 and the PORT2, that are inoperable combinations, cannot be accepted. Instead, the present embodiment includes a detection circuit 412. The detection circuit 412 activates a signal WFBDN when the write operation is requested in the PORT1 and the PORT2 at the same time. The detection circuit 412 activates a signal RFBDN when the read operation is requested in the PORT1 and the PORT2 at the same time. Further, the detection circuit 412 activates a signal ATBMON when the address transition detection signal becomes “L”. By using these signals, controls such as rewriting data that could not be written previously and rereading data that could not be read previously will be possible.

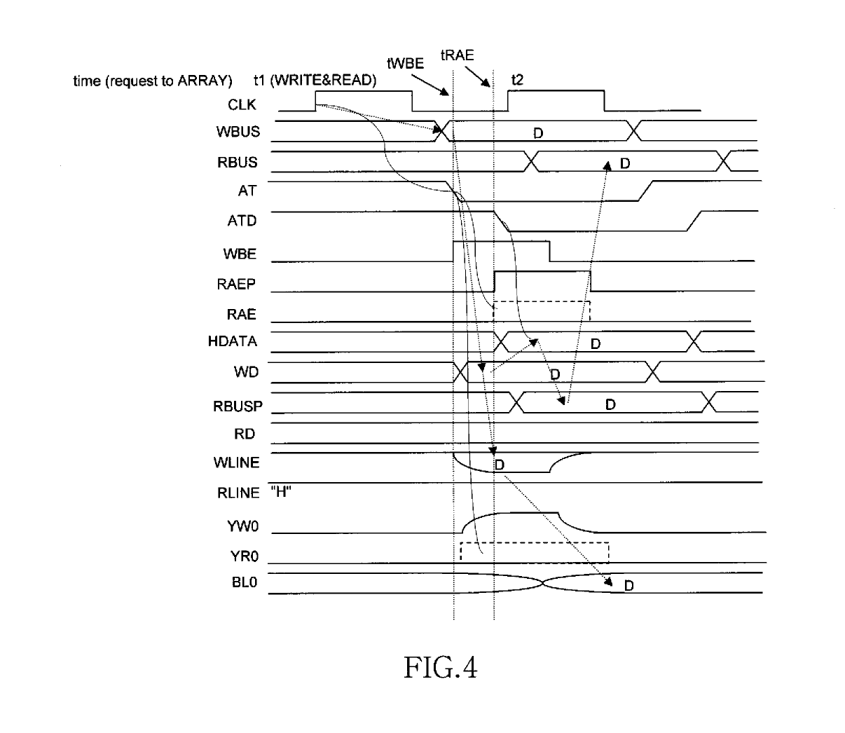

FIG. 4 is a timing diagram showing an operation timing when the write request and the read request are issued at the same time and the read address is the same as the write address.

First, when an address corresponding to a bit line pair BL0 is specified and the write operation upon the PORT1 is requested at a time t1, data D is written in a write bus WBUSa in synchronization with the time t1. The write buffer activation signal WBEa rises at a time tWBE in synchronization with the time t1. Thus, the data D is fetched into the hold circuit 403 and supplied to the data line WLINE for write by a write buffer 404. The column select signal YW0 for write then rises and the data D is written in the bit line pair BL0.

Meanwhile, the read operation upon the PORT2 is also required at the time t1 by specifying the address corresponding to the bit line pair BL0. That is, because the write address is the same as the read address, the address transition detection signal AT becomes “L”. Thus, the column select signal YR0 for read is maintained as an inactivated state. At this time, the data D is being written in the bit line pair BL0 by the previous write request and thus the signal amount is still small. If the data D is read during this timing, it may be broken. Because AT=″L″, however, the data D is not read. Therefore, the write operation continues stably without special load changes in the bit line pair BL0. That is, the read data usually read to the data line RLINE for read is not provided. The activation signal RAEPb then rises at a time tRAE but the activation signal RAEb does not rise because AT=“L”, so that the read amplifier 405 is not activated either. The write data D is held by the register 407 in synchronization with the activation signal RAEPb and transferred to a signal line HDATA. As the delay address transition detection signal ATD is also “L”, the multiplexer 408 selects the input 0 and the write data D is read to the read bus RBUSb as the read data.

As described above, when the write request and the read request are issued at the same address, the write data is written in the array and also returned as the read data. With this arrangement, the read request can be received.

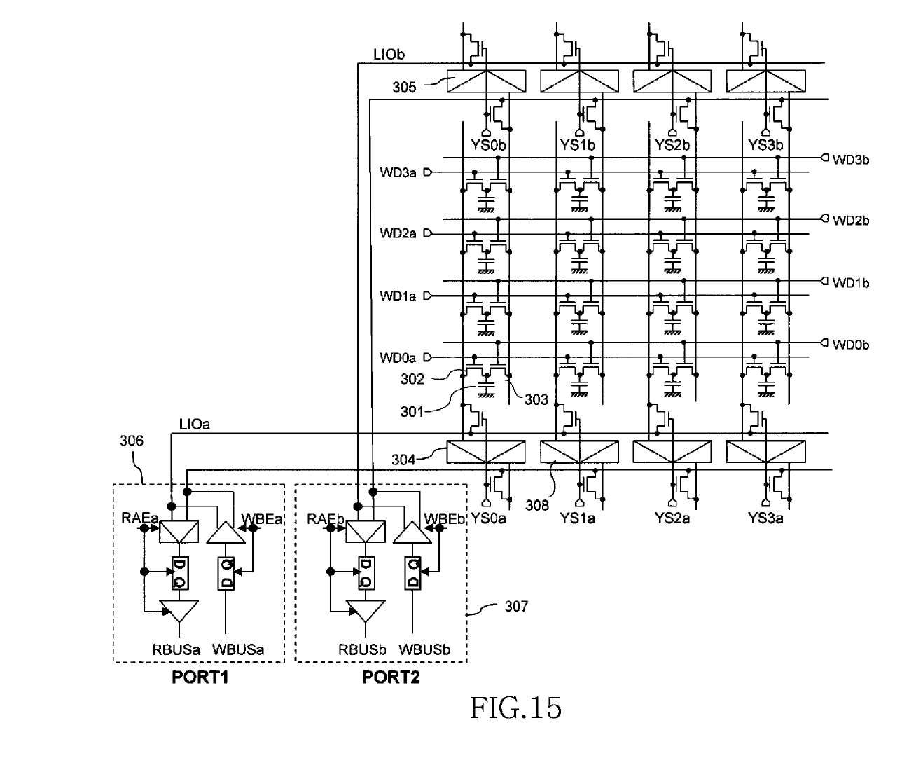

It is not that the configuration of the memory cell array in the semiconductor memory device according to the present invention cannot be the configuration shown in FIG. 15, and the memory cell array shown in FIG. 15 can be used. This is applicable to the following embodiments.

A second embodiment of the present invention is described next.

The second embodiment is obtained by further developing the first embodiment described above. According to the second embodiment, a dual-port memory that can perform the simultaneous read operations in the PORT1 and the PORT2 and the simultaneous write operations in the PORT1 and the PORT2 by specifying different column addresses in addition to the simultaneous read and write operations for the same row address is provided.

While the data lines and the column select signals are sorted into the ones for write operation and the ones for read operation in the first embodiment, they are sorted into the ones for the PORT1 and the ones for the PORT2 in the second embodiment. Specifically, the dual-port memory is configured as follows. A write path of the memory core is assigned to the PORT1 and a read path is assigned to the PORT2 so that when the PORT1 performs the write operation and the PORT2 performs the read operation, these operations can be performed at the same time. Further, a write function is added to the PORT2 and the data lines are I/O lines so that when the PORT1 performs the write operation and the PORT2 performs the write operation, these operations can be performed at the same time. Assume that such a configuration is called “configuration A”. On the other hand, the write path of the memory core is assigned to the PORT2 and the read path is assigned to the PORT1 so that when the PORT2 performs the write operation and the PORT1 performs the read operation, these operations can be performed at the same time. Further, the write function is added to the PORT1 and the data lines are I/O lines so that when the PORT2 performs the write operation and the PORT1 performs the write operation, these operations can be performed at the same time. Assume that such a configuration is called “configuration B”. By bringing together the configuration A and the configuration B, a configuration that the PORT1 and the PORT2 are provided separately is obtained.

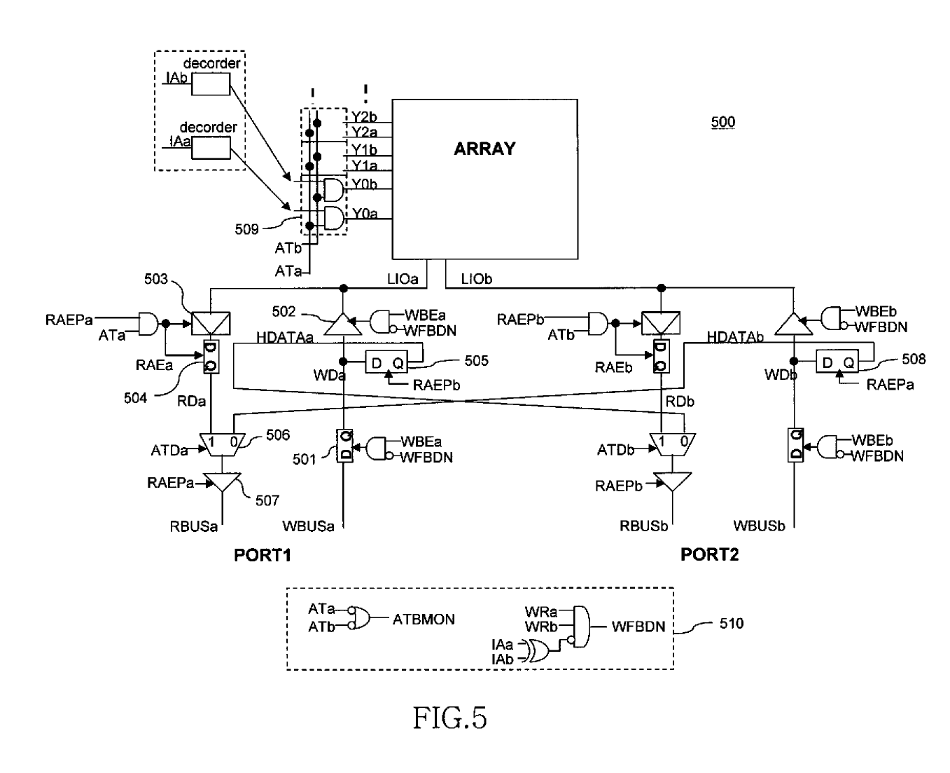

FIG. 5 is a circuit diagram showing a configuration of principal parts of a semiconductor memory device 500 according to the second embodiment. The semiconductor memory device 500 according to the second embodiment is a DRAM.

As shown in FIG. 5, during the write operation using the PORT1, write data is fetched by a hold circuit 501 and supplied by a write buffer 502 to an I/O line LIOa. During the read operation using the PORT1, read data supplied through the I/O line LIOa is amplified by a read amplifier 503, held by a hold circuit 504, and selected by a multiplexer 506. The resultant data is then outputted from a tri-state buffer 507. Such processes are performed in the PORT1 at independent timings. When the read operation of the PORT1 and the write operation of the PORT2 are performed at the same address, the write data of the PORT2 needs to be used as the read data of the PORT1. In this case, data held not by the hold circuit 504 but by a hold circuit 508 in the PORT2 is selected by the multiplexer 506. Accordingly, the hold circuit 508 in the PORT2 needs to be operated at the timing of the PORT1. Because this description also applies to the PORT2, duplicate descriptions thereof will be omitted.

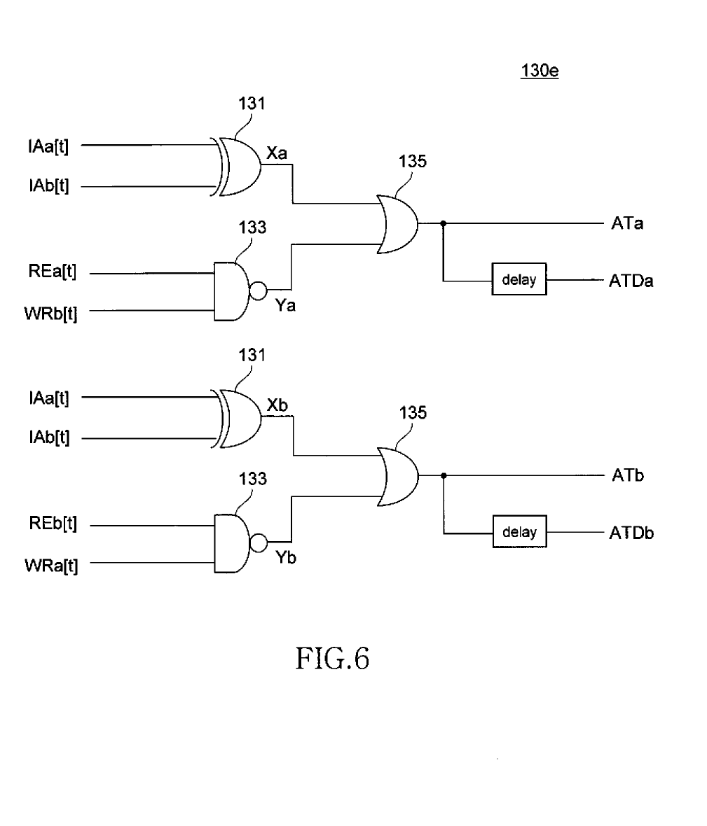

Address transition detection signals ATa and ATb controlling a column select driver 509, the read amplifier 503, and the multiplexer 506 are generated by a detection circuit 130e shown in FIG. 6. In the detection circuit 130e shown in FIG. 6, when the PORT1 is for read and the PORT2 is for write and the address of the PORT1 is the same as that of the PORT2, the address transition detection signal ATa is at the L level. Similarly, when the PORT1 is for write and the PORT2 is for read and the address of the PORT1 is the same as that of the PORT2, the address transition detection signal ATb is at the L level.

When the address transition detection signal ATa is “L”, the column select signal and the read amplifier 503 in the PORT1 are not driven and the write data of the PORT2 is utilized as the read data of the PORT1. The write operation in the PORT2 is normally performed. Similarly, when the address transition detection signal ATb is “L”, the column select signal and the read amplifier in the PORT2 are not driven and the write data of the PORT1 is utilized as the read data of the PORT2. The write operation in the PORT1 is normally performed.

The dual-port memory according to the present embodiment includes a detection circuit 510. The detection circuit 510 generates a signal WFBDN activated when the simultaneous write operation in the PORT1 and the PORT2 by specifying the same address, which is an inhibited combination of operations, is requested and a signal ATBMON activated when ATa or ATb becomes “L”. By using these signals, controls such as writing data that could not be written again and reading data that could not be read again will be possible. In the circuit diagram shown in FIG. 5, it is designed not to operate when an inhibited access is requested.

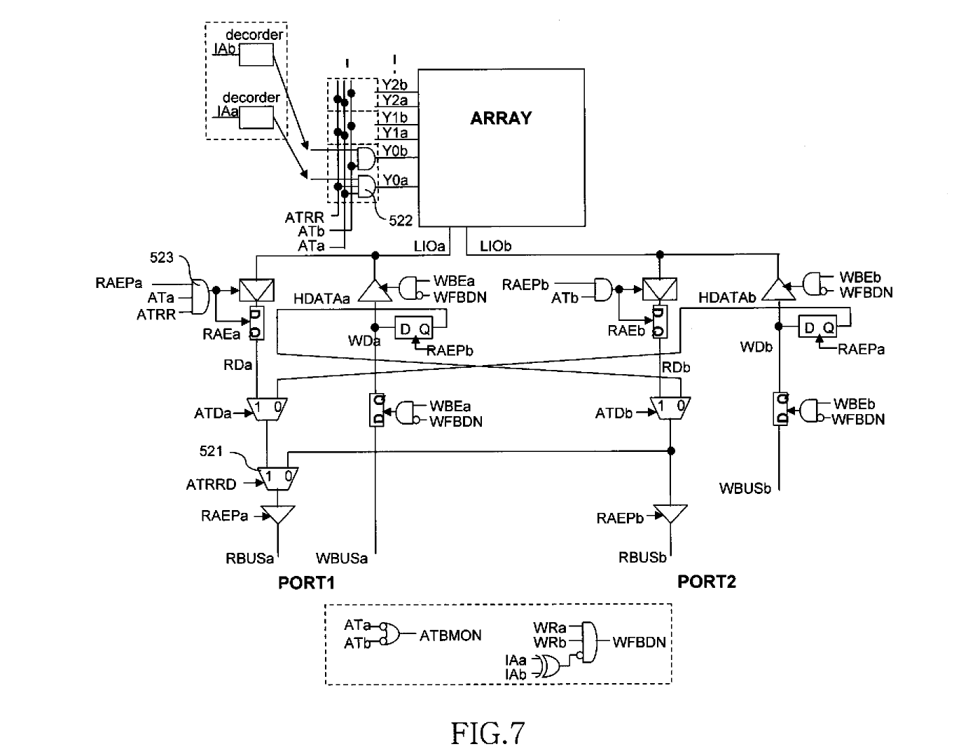

In the present embodiment, the simultaneous read operation in the PORT1 and the PORT2 by specifying the same address is not inhibited. When the signal amount obtained by the simultaneous read operation can ensure merely the signal amount of one read operation, as shown in FIG. 7, only the read operation for one port is performed and the resultant read data is preferably shared by the PORT1 and the PORT2.

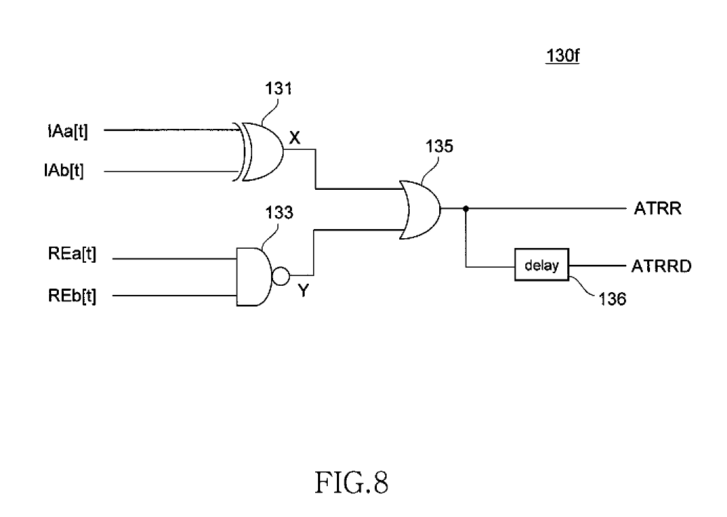

In the circuit shown in FIG. 7, when the read operation is performed in the PORT1 and the PORT2 for the same address, the PORT2 performs the read operation as usual. On the other hand, the PORT1 receives the read data of the PORT2 through a multiplexer 521, stops a column select driver 522 for PORT1 by an address transition detection signal ATRR, and inhibits activation of a read amplifier 523 for PORT1. The address transition detection signal ATRR can be generated by a detection circuit 130f shown in FIG. 8. An address transition detection signal ATRRD is a signal obtained by delaying the address transition detection signal ATRR until read amplifier's amplification timing.

A third embodiment of the present invention is described next.

The third embodiment provides a dual-port memory that can perform the read operation and the write operation at the same time for the same row address by performing an operation different from that of the first embodiment. Specifically, the dual-port memory is configured as follows. Arbitration circuits sharing a write path by a dual-port and sharing a read path by the dual-port are added to the memory core that can perform the read operation and the write operation at the same time. According to the arbitration method, when one port is assigned to the write path, the other port is assigned to the read path. With this arrangement, the simultaneous read and write operations in the dual-port can be realized by operating the write path and the read path at the same time.

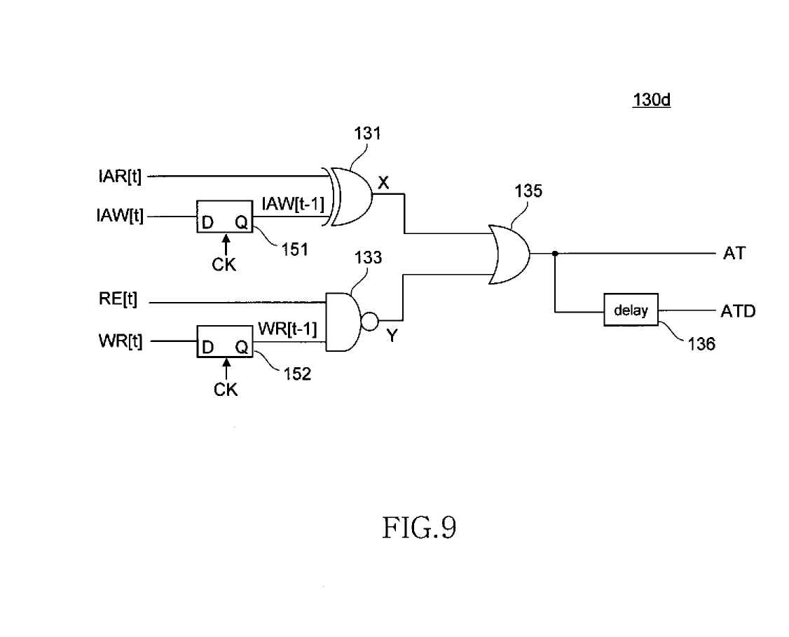

The specific circuit configuration is the same as that of the dual-port memory according to the first embodiment shown in FIG. 1, and the address transition detection signal AT uses a detection circuit 130d shown in FIG. 9. The detection circuit 130d shown in FIG. 9 has a circuit configuration obtained by adding DQ latches 151 and 152 to the detection-circuit 130c shown in FIG. 3. DQ flip-flops are used conveniently for these DQ latches. The current read address IAR[t] and a write address IAW[t−1] one cycle before the current cycle are supplied to the EXOR gate 131. The current read-state flag RE[t] and a write-state flag WR[t−1] one cycle before the current cycle are inputted to the NAND gate 133. The address transition detection signal AT thus becomes “L” only when the read request is issued in the cycle subsequent to the write request and the read address is the same as the write address. When the address in the write operation is the same as the one in the read operation in the write-to-read operation, it becomes AT=″L″ and an avoidance operation is performed. Accordingly, written data can be read first and then data can be written without rate-controlling the cycle time tCK. Because write in the array is delayed by a read amplifier activation wait time in such an operation, strict operations are imposed upon the spec tDPL(tWR) that determines the time when a pre-charge command can be inputted after a write command.

According to the first embodiment described above, when the write request and the read request are provided for the same address, the write operation is performed actually for the write request but the read operation is not performed actually for the read request and the write data is returned as the read data. According to the third embodiment, when the write request and the read request are provided for the same address, the read operation is performed actually for the read request and then the write operation is performed actually for the write request. As for the configuration of main parts of the semiconductor memory device according to the third embodiment, the circuit configuration shown in FIG. 1 can be used as it is.

In such a case, the activation of the write buffer activation signal WBE must be delayed with respect to the activation signal RAEP in response to the read request. As a result, the write operation goes on into the next cycle.

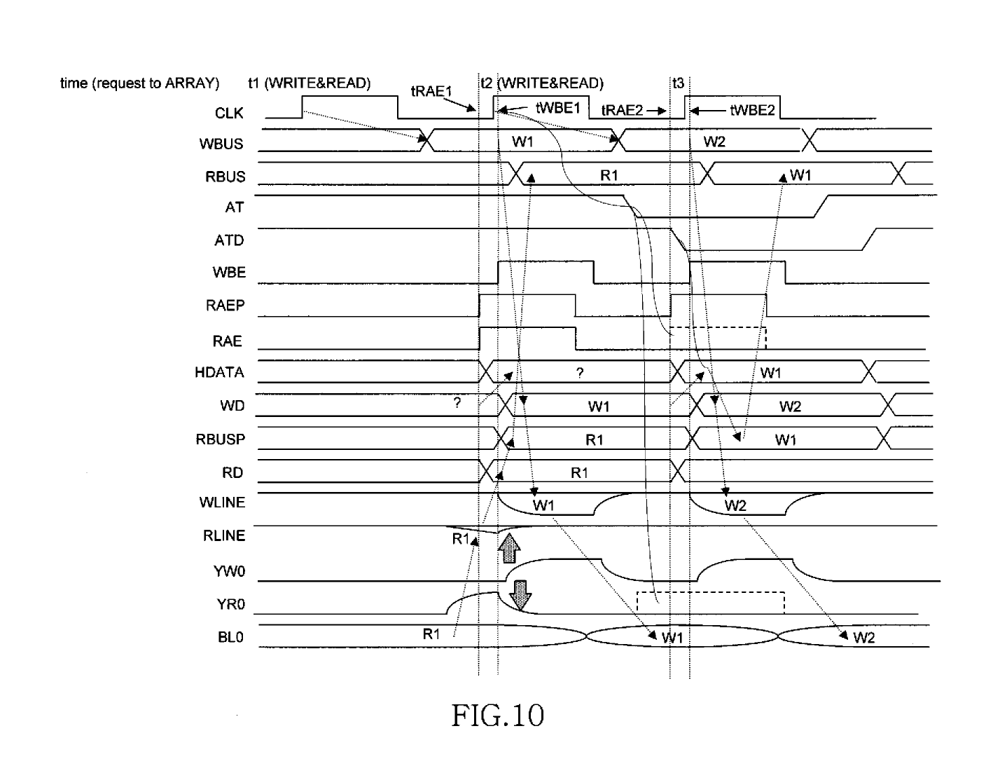

FIG. 10 is a timing diagram showing an operation timing when the simultaneous issue of the write request and the read request is performed consecutively and the read address is the same as the write address.

First, when the address corresponding to the bit line pair BL0 is specified and the read operation upon the PORT1 is requested at the time t1, the column select signal for read YR0 is activated because AT=″H″, read data R1 is read form the bit line pair BL0 and supplied to the data line RLINE for read. The activation signal RAEPa then rises at a time tRAE1 corresponding to the time t1 and the activation signal RAEa also rises because AT=″H″. The data R1 is thus amplified by the read amplifier 405 and held by the hold circuit 406. The multiplexer 408 then selects the input 1 and the read data R1 is outputted via the multiplexer 408 to the read bus RBUSa.

Meanwhile, the write operation upon the PORT2 is also requested at the time t1 by specifying the address corresponding to the bit line pair BL0. Data W1 is written in the write bus WBUSb in synchronization with the time t1. The write buffer activation signal WBEb rises at a time tWBE1 later than the time tRAE1. The data W1 is thus held by the hold circuit 403 and supplied to the data line WLINE for write by the write buffer 404. The column select signal for write YW0 then rises and the data W1 is written in the bit line pair BL0. Because YR0 and YW0 have the same address and select the same bit line pair BL0, fall of YR0 may be required to write the data W1 easily. Because the data R1 has been already held by the hold circuit 406, any problem will not occur.

Next, when the address corresponding to the bit line pair BL0 is specified and the read operation upon the PORT1 is requested again at the time t2, the address transition detection signal AT becomes “L” because the address corresponding to the current read request is the same as the address corresponding to the write request in the previous cycle. Accordingly, the column select signal YR0 for read that rises in usual cases does not rise. At this time, the data W1 is being written in the bit line pair BL0 by the previous write request and thus the signal amount is still small. Therefore, if the data W1 is read during this timing, it may be broken. Because it becomes AT=″L″, however, the data W1 is not read. The write operation continues stably without special load changes in the bit line pair BL0. That is, the read data usually read to the data line RLINE for read is not provided. The activation signal RAEPa then rises at a time tRAE2 but the activation signal RAEa does not rise because AT=“L”, so that the read amplifier 405 is not activated either. Meanwhile, the write data W1 is held by the register 407 in synchronization with the activation signal RAEPa and transferred to the signal line HDATA. As the delay address transition detection signal ATD is also “L”, the multiplexer 408 selects the input 0 and the write data W1 is read to the read bus RBUSa as the read data.

Meanwhile, the write operation upon the PORT2 is also requested at the time t2 by specifying the address corresponding to the bit line pair BL0. Data W2 is written in the write bus WBUSb in synchronization with the time t2. The write buffer activation signal WBEb rises at a time tWBE2 later than the time tRAE2. The data W2 is thus fetched into the hold circuit 403 and supplied to the data line WLINE for write by the write buffer 404.

Even if the write request and the read request are received at the same address, the operation that written data is read first and then the data is written can be realized without rate-controlling a cycle time tCK. Because write in the array is delayed by a read amplifier timing wait time in the operation described in the third embodiment, strict operations are imposed upon the spec tDPL(tWR) that determines the time when a pre-charge command can be inputted after a write command.

A fourth embodiment of the present invention is described.

The fourth embodiment is obtained by further developing the third embodiment. According to the present embodiment, a dual-port memory that can perform the simultaneous read operation and the simultaneous write operation for different addresses in addition to the simultaneous read and write operations for the same row address is provided.

The data lines and the column select signals are sorted into the ones for a write operation and the ones for a read operation in the third embodiment. In the fourth embodiment, a set for a write operation and a set for a read operation are further prepared and these sets are used for the PORT1 and the PORT2, respectively. Specifically, the dual-port memory is configured as follows. As described above, the third embodiment also provides the memory core that can perform the read operation and the write operation at the same time. The write path of the memory core according to the third embodiment is assigned to the PORT1 and the read path is assigned to the PORT2 so that when the PORT1 performs the write operation and the PORT2 performs the read operation, these operations can be performed at the same time and the read operation of the PORT 2 in the next cycle can be processed. Assume that such a configuration is called a configuration A. The write path of the memory core according to the third embodiment is assigned to the PORT2 and the read path is assigned to the PORT1 so that when the PORT2 performs the write operation and the PORT1 performs the read operation, these operations can be performed at the same time and the read operation of the PORT1 in the next cycle can be processed. Assume that such a configuration is called a configuration B. By bringing together the configuration A and the configuration B, a configuration that two kinds of the third embodiment are included at the same time while the PORT1 and the PORT2 are provided separately with having a set for a write operation and a set for a read operation, respectively can be obtained. However, the configuration of the third embodiment cannot handle a combination of the write operation and the read operation in the next cycle at the same port. A bypass register is thus provided so as to process the read operation of the PORT1 in the next cycle to the write operation of the PORT1. Similarly, a bypass register is provided so as to process the read operation of the PORT2 in the next cycle to the write operation of the PORT2. As a result, any operations can be handled.

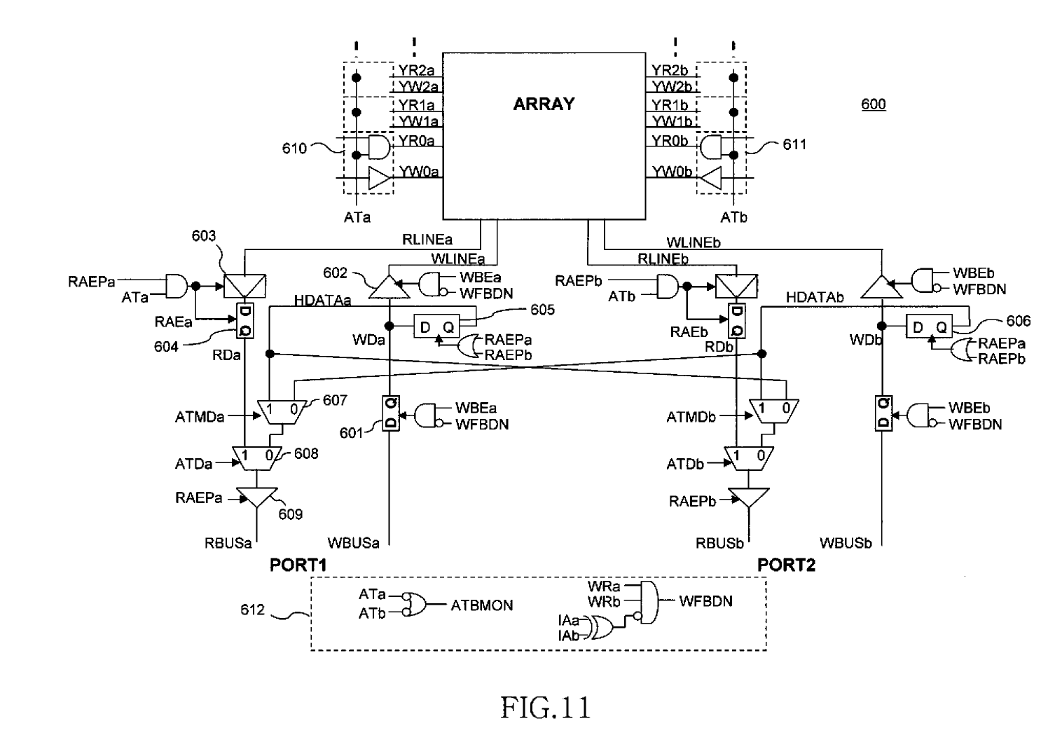

FIG. 11 is a circuit diagram showing a configuration of principal parts of a semiconductor memory device 600 according to the fourth embodiment. The semiconductor memory device 600 according to the present embodiment is a DRAM.

As shown in FIG. 11, during the write operation in the PORT1, write data supplied from a write bus WBUSa is fetched by a hold circuit 601 and supplied by a write buffer 602 to a data line WLINEa for write. During the read operation in the PORT1, read data read from a data line RLINEa for read is amplified by a read amplifier 603, held by a hold circuit 604, and selected by multiplexers 607 and 608. The resultant data is then outputted to a read bus RBUSa. Such processes are performed in the PORT1 at independent timings. The same is applied to the PORT2.

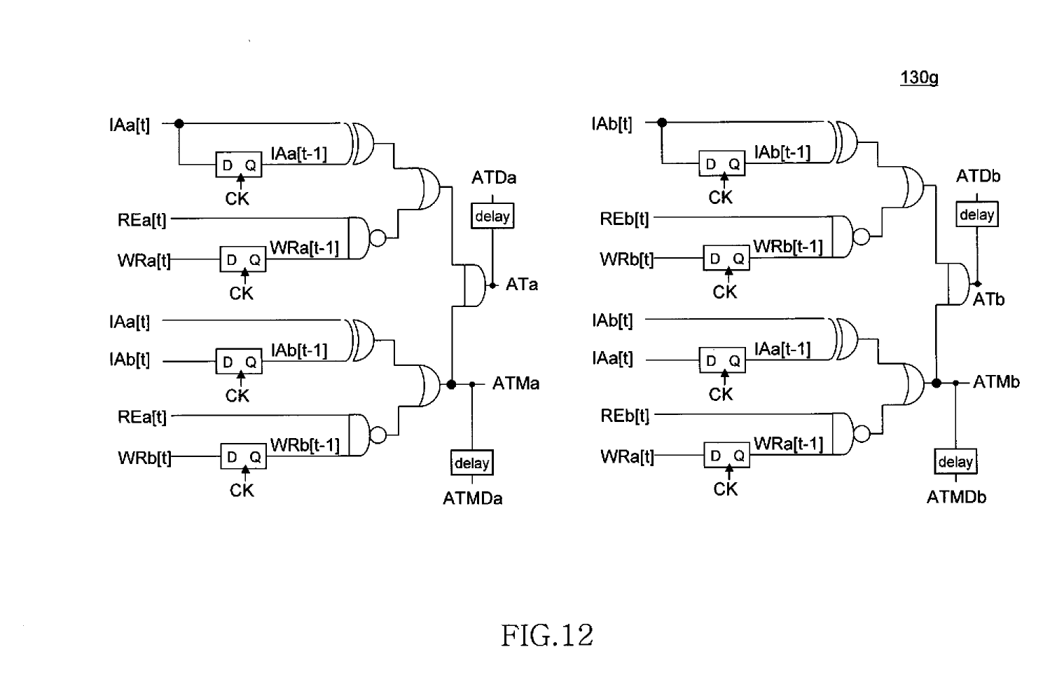

Note that, when the read operation of the PORT1 and the write operation of the PORT1 or the PORT2 are performed at the same address, the data of the port that is performing write needs to be used. Accordingly, hold circuits 605 and 606 are operated at the timing of OR of the PORT1 and the PORT2. The multiplexer 607 selects the data held in the PORT1 or the data held in the PORT2. The multiplexer 608 then determines whether the data read from the array or the data held is used. The address transition detection signals ATa and ATb controlling column select drivers 610 and 611, the read amplifier 603, and the multiplexers 607 and 608 need to be generated by a detection circuit 130g shown in FIG. 12.

The detection circuit 130g shown in FIG. 12 has the address transition detection signal ATa as the L level when the PORT1 performs the write-to-read operation and the write operation and the read operation are performed for the same address or when the PORT1 performs the read operation after the PORT2 performs the write operation and the write address of the PORT2 is the same as the read address of the PORT1. When the PORT1 performs the read operation after the PORT2 performs the write operation and the write address of the PORT2 is the same as the read address of the PORT1, a signal ATMa is set to be the L level. Similarly, when the PORT2 performs the write-to-read operation and the write operation and the read operation are performed for the same address or when the PORT2 performs the read operation after the PORT1 performs the write operation and the write address of the PORT1 is the same as the read address of the PORT2, the address transition detection signal ATb is set to be the L level. When the PORT2 performs the read operation after the PORT1 performs the write operation and the write address of the PORT1 is the same as the read address of the PORT2, a signal ATMb is set to be the L level.

As shown in FIG. 11, when the address transition detection signal ATa=“L”, the column select driver 610, the read amplifier 603, and the hold circuit 604 for the PORT1 are not driven and the write operation is performed in the writing port. The signal ATMa becomes H or L depending on the writing port and read of the data used for the write operation in the writing port serving as substitute data is controlled.

The dual-port memory according to the present embodiment includes a detection circuit 612. The detection circuit 612 has the same configuration as the detection circuit 510 shown in FIG. 5 and functions as the detection circuit 510. Also in the present embodiment, it is designed not to operate when an inhibited access is requested.

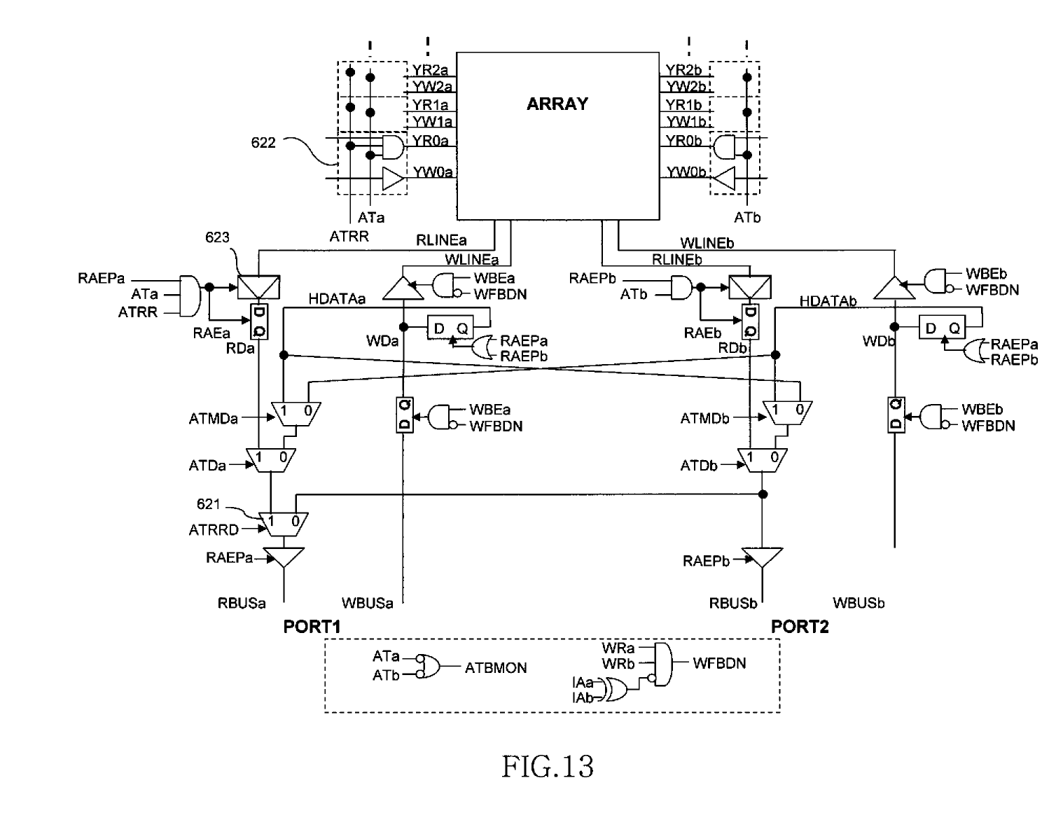

In the present embodiment, the simultaneous read operation in the PORT1 and the PORT2 by specifying the same address is not inhibited. When the signal amount obtained by the simultaneous read operation can ensure merely the signal amount of one read operation, as shown in FIG. 13, only the read operation for one port is performed and the resultant read data is preferably shared by the PORT1 and the PORT2.

In the circuit shown in FIG. 13, when the read operation is performed in the PORT1 and the PORT2 for the same address, the PORT2 performs the read operation as usual. On the other hand, the PORT1 receives the read data of the PORT2 through a multiplexer 621, stops a column select driver 622 for the PORT1 by an address transition detection signal ATRR, and inhibits activation of a read amplifier 623 for the PORT1. The address transition detection signal ATRR can be generated by the detection circuit 130f shown in FIG. 8. An address transition detection signal ATRRD is a signal obtained by delaying the address transition detection signal ATRR until the read amplifier's amplification timing.

Because write in the array is delayed by the read amplifier's timing wait time in this operation, operations become difficult with respect to the spec tDPL(tWR) that determines the time when a pre-charge command can be inputted after a write command like the third embodiment.

It is apparent that the present invention is not limited to the above embodiments, but may be modified and changed without departing from the scope and spirit of the invention.

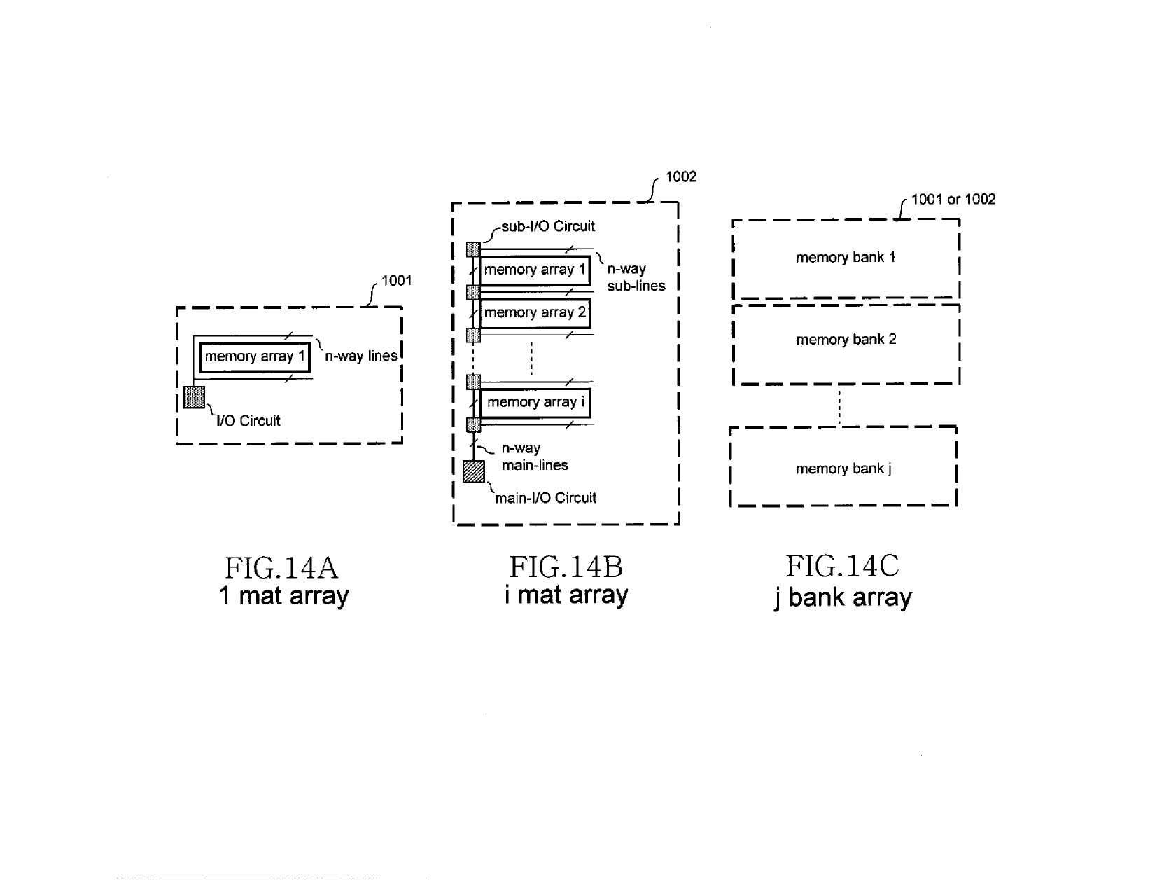

For example, data lines that connect the input/output circuit to the memory array in the above embodiments can be ones with a hierarchical configuration. Any number of hierarchies can be used in the configuration. The present invention can be applied to a one mat array configuration 1001 shown in FIG. 14A as described above. Even in a case of a multiple mat array configuration 1002 with a hierarchical data line configuration used for arrays of normal memory devices as shown in FIG. 14B, a sub input/output circuit is connected via a sub data line to a memory array and a main input/output circuit is connected via a main data line, the sub input/output circuit, and the sub data line to the memory array. Accordingly, the present invention can be applied in both cases of the sub input/output circuit and the main input/output circuit. Needless to mention, as shown in FIG. 14C, banks that can be operated independently can be provided.

What is claimed is:

1. A semiconductor memory device comprising:
a memory cell array including a plurality of word lines, a plurality of bit lines, a plurality of DRAM cells arranged at intersections of the word lines with the bit lines, a plurality of sense amplifiers connected to corresponding bit lines, and a first column switch and a second column switch assigned to each of the sense amplifiers;
a first data line and a second data line connected via the first column switch and the second column switch to the sense amplifiers, respectively;
a first port and a second port each of which can input a write data to be inputted to the memory cell array and can output read data outputted from the memory cell array; and
an input/output circuit that connects the first and second ports to the first and second data lines.

2. The semiconductor memory device as claimed in claim 1, wherein the word lines are provided so as to be common to the first port and the second port.

3. The semiconductor memory device as claimed in claim 1, wherein the input/output circuit includes:
a first write path that supplies the write data inputted to the first port to the first data line;
a second write path that supplies the write data inputted to the second port to the first data line;
a first read path that supplies the read data read through the second data line to the first port; and
a second read path that supplies the read data read through the second data line to the second port.

4. The semiconductor memory device as claimed in claim 1, wherein the input/output circuit includes:
a first write path that supplies the write data inputted to the first port to the first data line;
a second write path that supplies the write data inputted to the second port to the second data line;
a first read path that supplies the read data read through the first data line to the first port; and
a second read path that supplies the read data read through the second data line to the second port.

5. The semiconductor memory device as claimed in claim 4, wherein
both the first data line and the second data line include a read line and a write line,
the first write path supplies the write data inputted to the first port to a write line of the first data line,
the second write path supplies the write data inputted to the second port to a write line of the second data line,
the first read path supplies the read data read through a read line of the first data line to the first port, and
the second read path supplies the read data read through a read line of the second data line to the second port.

6. The semiconductor memory device as claimed in claim 1, wherein the input/output circuit includes a bypass circuit that supplies the write data inputted to the first port to the second port and supplies the write data inputted to the second port to the first port.

7. The semiconductor memory device as claimed in claim 6, wherein
the input/output circuit further includes a detection circuit that detects matching between a write address for the first port and a read address for the second port and matching between a write address for the second port and a read address for the first port, and
the bypass circuit supplies the write data supplied to the first write path to the second read path, or supplies the write data supplied to the second write path to the first read path in response to matching being detected by the detection circuit.

8. The semiconductor memory device as claimed in claim 7, wherein the bypass circuit includes:
a first bypass circuit that supplies the write data on the first write path to the second read path; and
a second bypass circuit that supplies the write data on the second write path to the first read path.

9. The semiconductor memory device as claimed in claim 3, wherein the input/output circuit further includes a bypass circuit that supplies the write data supplied to the first write path to the first read path, or supplies the write data supplied to the second write path to the second read path.

10. The semiconductor memory device as claimed in claim 8, wherein the input/output circuit further includes a circuit that supplies the read data on the second read path to the first read path.

11. The semiconductor memory device as claimed in claim 1, wherein the first data line and the second data line have a hierarchy structure.

12. A device comprising:
a memory cell array including a plurality of word lines, a plurality of bit lines, and a plurality of memory cells arranged at intersection of the word lines with the bit lines;
a first data line electrically connected to first selected one or ones of the bit lines;
a second data line electrically connected to second selected one or ones of the bit lines;
a first and second ports each of which may input a write data to be inputted to the memory cell array and may output read data outputted from the memory cell array; and
an input/output circuit that connects the first and second ports to the first and second data lines.
